(19) United States
(12) Patent Application Publication
(10) Pub. No.: US 2024/0004005 A1
(43) Pub. Date: Jan. 4, 2024

(54) TRANSCEIVER COIL ARRANGEMENT FOR AN MAS NMR PROBE HEAD AND METHOD FOR DESIGNING A TRANSCEIVER COIL ARRANGEMENT

(71) Applicant: Bruker Switzerland AG, Fällanden (CH)

(72) Inventor: Nicolas FREYTAG, Binz (CH)

(21) Appl. No.: 18/344,231

(22) Filed: Jun. 29, 2023

(30) Foreign Application Priority Data
Jul. 1, 2022 (DE) 102022206768

(51) Int. Cl. G01R 33/34; G01R 33/00

(52) U.S. Cl. CPC G01R 33/34053; G01R 33/0052

(57) ABSTRACT

A transceiver coil arrangement for an MAS NMR probe head has a first transceiver coil with a longitudinal axis Z′ for generating a first HF magnetic field B1, the first transceiver coil having at least one solenoid-shaped section with an electrical conductor having a path width W and N≥3 windings, wherein all windings run around the longitudinal axis Z′ of the transceiver coil 1. The electrical conductor has a slope S and each half-winding is tilted at a tilt T relative to the longitudinal axis Z′, wherein T≠0 for at least a portion of the half-windings. According to the invention, at least two of the following variables change over the course t of the length of the electrical conductor: Tilt T=T(t), slope S=S(t), conductor path width W=W(t), allowing the transceiver coil to be optimized to improve the homogeneous region.

### BACKGROUND OF THE INVENTION

The invention relates to a transceiver coil arrangement for a magic angle spinning nuclear magnetic resonance (MAS NMR) probe head having a first transceiver coil with a longitudinal axis Z′ for generating a first HF magnetic field B1.

A transceiver coil arrangement with tilted windings for an MAS NMR probe head is known from Sun et al., The Tilted Coil for NMR Experiments, J. Magn. Reson., Series A, Vol. 105, p. 145-150 (1993) and patent document U.S. Pat. No. 6,359,437.

In an MAS probe head, the transceiver coil arrangement typically stands at a magic angle of 54.7° to the static magnetic field BC (main field magnet).

It is known from Sun et al. and U.S. Pat. No. 6,359,437 that solenoid-shaped transceiver coils for NMR-MAS probe heads are designed at an angle of tilt relative to the axis of the solenoid coil, so that the high-frequency B1 field produced by the solenoid coil is as perpendicular as possible to the static BC field.

In Sun et al., an attempt is made to increase the sensitivity of an NMR coil by using an angle of tilt ψ=90-φ_{MAS}. They reach up to 17% shorter pulse angles with the same transmitted power for an MAS arrangement. In Sun et al., it is assumed that the generated B1 fields generate spatially constant angles and are independent of the specific implementation of the coil with an extended conductor cross section. Off-axis effects in the edge region of the coils are not investigated in Sun et al.

In U.S. Pat. No. 6,359,437, an attempt is made to find a solution for the generated HF magnetic fields B1 by designing a more complex coil geometry, in which the HF magnetic fields B1 come to lie in the XY-plane in the entire active region of the coil. The target function of the optimization in U.S. Pat. No. 6,359,437 is therefore the absence of z-components of the generated B1 field in a cylindrical measurement volume. In particular, geometries are proposed that deviate from a solenoid shape with windings that do not run around the longitudinal axis of the coil. The coil geometry shown in U.S. Pat. No. 6,359,437 is to be used in combination with a second coil/resonator, wherein the HF magnetic field generated by the second coil is not to have any Bz components. In U.S. Pat. No. 6,359,437, it is assumed that an NMR measuring head with coils that produce an HF magnetic field with B=Bxy also have the maximum sensitivity when used in a measuring head with more than one transceiver coil arrangement, i.e., also for cross-polarization measurements. Shielding effects by conductors of the coil are not taken into account.

The solutions of Sun et al. and U.S. Pat. No. 6,359,437 proceed from a vanishing conductor path width of (unexpanded conductors) and do not represent the best solution for finite conductor paths, but in particular very small distances between the conductor paths.

In addition to coil geometries based on conductors with a round or oval cross-section, it is also known to use strip-shaped conductors for NMR probe heads. In particular, such coil geometries can be structured on a cylindrical jacket-shaped conductor (e.g., by structurally applying a metallic layer on a substrate with a cylindrical surface or by structuring a uniformly applied conductor using subtractive manufacturing processes) or cut out from a cylindrical jacket-shaped conductor. These manufacturing methods enable greater freedom in the design of the coil geometry, in particular a variable pitch.

Privalov et al., Homogeneity for Solid-State NMR Applications, J. Magn. Reson., Series A, Vol. 123, p. 157-160 (1996) describes transceiver coils with a band-shaped conductor. To optimize axial homogeneity, the conductor path width is reduced towards the axial ends. To minimize radial inhomogeneity, the conductor distance between the windings is kept as small and constant as possible. However, the efficiency of this transceiver coil is not optimal.

### SUMMARY OF THE INVENTION

The invention provides a transceiver coil for NMR-MAS applications for which the homogeneous region is improved in the axial and in the radial direction within the field of view (region within the transceiver coil in which a probe to be examined can be positioned and examined by means of NMR) and/or the strength of the HF magnetic Field B1 generated by the transceiver coil is increased at a given power.

According to the invention, at least two of the following variables change over the course t (i.e., the path followed by the conductor) along the length of the electrical conductor of the transceiver coil: Slope S=S(t), tilt T=T(t), conductor path width W=W(t).

A change in the slope S=S(t) can be realized by a change in the pitch P (slope of a winding), but also by a change in the local slope S within a winding with constant P.

The pitch P(n) of the nth winding is defined as P(t)=∫ₜₙ^{tn+1}S(t) dt the local slope S(t) of the windings (i.e., of the distance covered over a winding in the Z′ direction), wherein S(t) is the local slope, wherein tn is the running parameter t of the conductor profile at the beginning of the n-th winding, i.e., tn=0, 1, . . . .

For a constant pitch P, the local slope S can vary within one winding and can even reverse sign. The pitch P of a winding is to be referred to as positive when the Z′ coordinate of the center lines for tn+1 is greater than the Z′ coordinate at tn. This holds even if the Z′ coordinate in the interval between tn and tn+1 takes smaller values than at tn. The slope S of the windings and the conductor path width W or the ratio S/W of slope S and conductor path width W have an influence on axial homogeneity.

The multiple windings of the transceiver coil can also be realized as individual windings which are coupled inductively or capacitively. The pitch then describes the distance of the center lines of two adjacent individual windings.

The tilt T of the windings has an influence on the B1 amplitude (amplitude of the HF magnetic field B1 generated by the transceiver coil) and on radial homogeneity. The tilt T is defined as the amplitude of a sinusoidal modulation of the Z′ position of the conductor center plane over one winding. In the case of a coil with a T≠0 tilt, the local slope S within the first winding half differs from that in the second winding half. In the case of a tilt T=T(t) that varies over the course t of the length of the electrical conductor, the tilt is preferably constant in sections, in particular for at least one half-winding (half winding). The tilt T thus changes from half-winding to half-winding.

A coil with a T≠0 tilt can in principle also be described by a variable slope S′(t)=S(t)+T(t) cos(2πt+φ) (general slope). If S′(t) is written as a Fourier series, then T describes the (t=1)-periodic part of the slope. For each winding, the slope can be written as:

S′(t)=S₀+Σₖ₌₁^{∞}(S_{k,α}cos(k2πt)+S_{k,b} sin(k2πt)) wherein

S(t)=S′(t)−(S_{1,α}cos(2πt)+S_{1,b} sin(2πt)).

(S_{1,α} cos(2πt)+S_{1,b} sin(2πt)) can be written as T(t) cos(2πt+φ) where T is the inclination and φ is the direction of the inclination (usually φ=0 or φ=90°).

The conductor path width W is the width of the conductor path perpendicular to the conductor center. In the case of a conductor path width W=W (t) that varies over the course t of the length of the electrical conductor, the conductor path width can also vary within one winding.

The windings of the transceiver coil according to the invention are windings which run completely about the longitudinal axis Z′ of the transceiver coil, i.e., which describe a circle in a projection perpendicular to the longitudinal axis Z′.

In an advantageous embodiment, the transceiver coil is solenoid-shaped or the transceiver coil comprises exclusively solenoid-shaped winding sections (for example a solenoid-shaped forward winding section and a solenoid-shaped return winding section, see below).

In the transceiver coil according to the invention, the influences of various geometric factors of the transceiver coil on the sensitivity of the transceiver coil are utilized. In order to achieve an optimization of the coil sensitivity of transceiver coils with a conductor extended (perpendicular to the course of the conductor), according to the invention at least two of the above-mentioned parameters are selected such that they depend on a running parameter t along the electrical conductor of the transceiver coil, i.e., along the course of the electrical conductor.

The electrical conductor of the first transceiver coil may be designed as a band-shaped conductor. A band-shaped conductor has a thickness that is small in relation to the conductor path width (in particular smaller by at least one order of magnitude) and has a substantially rectangular cross section. The band-shaped conductor preferably comprises a substrate with a thin metal plating, in particular an HTS coating.

The conductor thickness d of the conductor (i.e., the extension of the electrical conductor in the radial direction relative to the longitudinal axis Z′ of the transceiver coil) may be at most 1 mm (preferably at most 200 μm) and/or is at least as large as twice the penetration depth of the RF current into the electrical conductor. Furthermore, it is advantageous if the conductor path thickness d is at least 20 μm, preferably at least 100 μm. The penetration depth is to be understood as the depth at which the current density has dropped to 1/e of the value at the conductor surface (skin effect). It is a function of the material of the electrical conductor and the frequency of the RF magnetic field generated therewith.

For conductors having a circular conductor cross-section (circular conductors), it is known that the optimum quality factor is achieved with a ratio of pitch to conductor path width P/W of P/W≈1.5-1.667 (depending on the length/diameter ratio of the solenoid coil). In the context of the invention, it has been recognized that, in transceiver coils from strip conductors, this ratio is significantly smaller, i.e., in contrast to a circular conductor, the conductor distance between two windings (gap width D) is significantly smaller than the conductor path width if the thickness of the strip conductor is small. Furthermore, this gap width D is not homogeneous over the entire length of the conductor: Edge effects of finite solenoid coils result in the magnetic field in the edge region no longer extending parallel to the Z′ axis but rotating “outwards.” This means that the gap width D between windings in the edge region of the transceiver coil should be selected to be greater than in the center, i.e., the ratio of gap width to conductor path width D/W should be greater at the edge than in the center. In contrast to circular-cylindrical conductors, a transceiver coil produced from strip-shaped conductors allows for a significantly higher design flexibility, in particular when it is produced by structuring from a tubular metal plating.

In a preferred embodiment of the transceiver coil according to the invention, the slope S changes over the course t of the length of the electrical conductor, and the conductor path width W changes within each winding. In particular, the conductor path width within each winding increases and decreases at least once in each case. Preferably, the conductor path width varies periodically.

Particularly advantageous is an embodiment with two maxima and two minima of the conductor path width per winding, in particular for transceiver coil arrangements having two transceiver coils in a cross-coil configuration. In this embodiment, the regions of the electrical conductor with minimum values for the conductor path width may be arranged offset by 180° relative to a rotation about the longitudinal axis Z′. Regions of the electrical conductor with minimum conductor width are then preferably arranged rotated by 90° with respect to the regions with maximum conductor width with respect to a rotation about the longitudinal axis Z′, i.e., are spaced apart from each other by a quarter of a winding.

The conductor width W preferably varies between 0.1 mm and 2 mm.

Furthermore, in the case of a combination of a first transceiver coil with T≠0 that generates an HF magnetic field lying substantially within the measurement sample in an X′Z′ plane of a Cartesian X′, Y′, Z′ coordinate system and a second coil that generates a second HF magnetic field B2, which in the measurement sample lies substantially in a Y′Z′ plane, an embodiment of the first transceiver coil is advantageous which has four maxima and four minima per winding, the minima being in the X′ and Y′ direction and the maxima being at 45° between X′ and Y′.

In a specific embodiment of the transceiver coil arrangement according to the invention, the slope S and the tilt T of the electrical conductor of the first transceiver coil changes along the course of the electrical conductor

The tilt T has two effects. First, a field component is produced in the X′-direction. This is advantageous in particular when the transceiver coil is used in a static magnetic field which is oriented along a Z-axis and the Z-axis is not collinear with the longitudinal axis Z′ of the transceiver coil. For a given transceiver coil, the circularly polarized component that rotates in the same direction as the nuclear precession is relevant for nuclear excitation (excitation field B1+), and the circularly polarized component that rotates opposite to the direction of the nuclear precession is relevant for signal reception (excitation field B1−), wherein: B1+=(B1x+i B1y)/2 and B1−=B1x−i B1y)/2. In other words, only field components in the X- and Y-plane, i.e., perpendicular to the direction of the static magnetic field, are relevant for the excitation and reception of NMR signals.

Excitation field B1+ and excitation field B1−can be maximized by adjusting the tilt T. For transceiver coils with a ratio of pitch to conductor path width P/W»1, i.e., for very narrow/thin conductors, the maximum for the excitation field B1+ is reached when the field generated by the transceiver coil comes to lie in the X′Z′-plane. However, this maximum pushes towards a lower tilt T when extensive conductors are used, i.e., when the conductor width W is increased, since shielding currents on the conductors reduce the efficiency of the transceiver coil.

As mentioned above, it was recognized within the scope of the invention that the orientation of the B1 field is unequal to the orientation in the center as in the edge region of a finite transceiver coil. If the longitudinal axis Z′ of the transceiver coil now assumes an angle not equal to 0° or 90° relative to the Z-axis, then B1+ above the longitudinal axis Z′ (i.e., for X′>0) is not equal to B1+ below the longitudinal axis Z′ (i.e., for X′<0). By adapting the tilt T in the edge region, B1+ can be homogenized over the entire sample volume in the edge region.

The variation of the tilt T along the length of the conductor makes it possible to maximize the efficiency of the transceiver coil under the condition of a radial minimum homogeneity of the B1+ field in the edge region.

Preferably, the tilt T at the axial ends of the first transceiver coil is smaller than at the axial center of the transceiver coil.

Under the condition that the longitudinal axis Z′ of the transceiver coil is at the magic angle to the Z-axis, a maximization of the efficiency with simultaneous optimization of radial homogeneity at the axial ends of the transceiver coil is achieved by a lower tilt T at the axial ends.

A specific embodiment of the transceiver coil arrangement according to the invention provides for the transceiver coil arrangement to comprise at least one further transceiver coil for generating a second HF magnetic field B2 radially outside the first transceiver coil, and for the first transceiver coil and the further transceiver coil to be arranged about the common longitudinal axis Z′ such that HF magnetic fields B1, B2 generated by the first transceiver coil and the further transceiver coil are oriented perpendicularly to one another.

The two transceiver coils are preferably tuned to different frequencies. HF magnetic fields B1, B2 perpendicular to one another means that the volume integral of the scalar product of the vectors B1(x,y,z) and B2(x,y,z) is approximately zero at least over the area of the field of view (FOV) of the two transceiver coils in which a measurement sample is situated; i.e., only the HF magnetic fields B1, B2 within the measurement sample are considered. In a specific embodiment, the orthogonality of the two HF magnetic fields B1 and B2 is achieved by a matching network, i.e., the HF magnetic fields B1 and B2 generated directly by the two transceiver coils do not have to be exactly orthogonal to one another.

In particular, the conductor path width W of the electrical conductor of the first transceiver coil may have a minimum value in the region in which the surface normal of the first transceiver coil is parallel to the second HF magnetic field B2. In other words, in the area of the surface of the first transceiver coil that the HF magnetic field B2 must penetrate to excite the measurement sample in the field of view, the conductor path width W of the electrical conductor of the first transceiver coil is minimal, in order to create a transparency region for B2.

The further transceiver coil is preferably a saddle coil or a resonator (e.g., a birdcage resonator, Alderman-Grant resonator, . . . ).

In yet another specific embodiment of the transceiver coil arrangement according to the invention, the electrical conductor of the first transceiver coil comprises a forward winding section and a return winding section, wherein the forward winding section comprises forward windings and, starting from a connection region, leads in a predetermined winding sense to an axial end of the transceiver coil, wherein the return winding section comprises return windings and, starting from the axial end of the first transceiver coil, leads in the predetermined winding sense to the connection region, the windings of the return winding section having a pitch P of opposite sign to those of the forward winding section, and in that forward and return windings of the electrical conductor, with the exception of crossover regions in which the forward and return windings cross over, are arranged on a common cylindrical jacket surface about the longitudinal axis Z′ (“crisscross geometry”).

The forward and return windings are therefore at the same radial distance around the longitudinal axis Z′, i.e., there are windings running in opposite directions on a common surface. The connection area is used to connect the electrical coil section to a matching network and may comprise connections for multiple electrical coil sections. The forward winding section and the return winding section form a coil section that runs between two terminals of the terminal section, so that the applied voltage is applied between the beginning of the forward windings and the end of the return windings of the respective coil section. In order to arrange the forward windings and return windings on a common cylinder surface, the forward windings and the return windings must cross each other. The crossovers are carried out on a section of the circumference (crossover area) that has as small an extension as possible, wherein preferably the electrical conductor of the forward winding section or of the return winding section remains on the cylinder surface, whereas the respective other electrical conductor crosses over the first electrical conductors in the form of a bridge element.

By means of this specific embodiment, the arrangement of the windings and of the connection region can be selected such that the potentials during operation of the transceiver coil are equal or similar in magnitude to comparable positions of adjacent windings (for example at the beginning of the winding or in the center or at the end). The potential is considered similar if U1/UN=(N/2-1)/(N/2) with U1 being the voltage over the first winding; and UN being the voltage over N windings. In a preferred embodiment, in which the coil section comprises a reversal winding which in operation has a point with potential 0 (which is set by a so-called balanced network), the forward windings and return windings of a coil section, with the exception of the reversal winding, are therefore preferably arranged in alternating fashion. In this way, the electric fields visible to an electrically conductive sample can be reduced, and at the same time other performance losses can be reduced. This embodiment is particularly advantageous for the examination of conductive measurement samples or measurement samples with high dielectric losses. The geometric arrangement of the conductor sections on a common cylinder surface according to the invention makes it possible to greatly minimize the electrical fields generated by the coils of the NMR probe head in the measurement sample. Electric fields can lead to performance losses both during transmission and during reception, for example the heating of the measurement sample, lengthening of pulse angles with limited transmission power, reduction of the signal-to-noise ratio, etc.

Multiple coil sections can also be provided, each comprising a forward winding section and a return winding section.

Preferably, both the forward winding section and the return winding section are designed to be solenoid-shaped. The forward windings and return windings are preferably arranged alternately.

The invention also relates to an MAS NMR probe head with a previously described transceiver coil arrangement, wherein the NMR probe head is designed to be arranged in an elongated bore of an NMR magnet. The elongated bore of the NMR magnet and the static magnetic field B0 produced by the NMR magnet are oriented along a Z-direction. The elongated extension of the NMR probe head housing also runs in the Z-direction, so that the NMR probe head can be inserted into the bore of the NMR magnet. The X direction is in the X′Z′-plane and Y′Y′.

The invention also relates to a method for designing a previously described transceiver coil arrangement, wherein an optimization is carried out. According to the invention, either the signal-to-noise ratio SNR of a predetermined NMR experiment is selected as the target function for optimization, or the target function comprises at least two variables which influence the signal-to-noise ratio (SNR). According to the invention, optimization is carried out by means of optimization parameters, of which at least two selected optimization parameters vary over the course of the length of the electrical conductor and are selected from the following parameters: Slope S, tilt T, conductor path width W.

An NMR experiment provides, in particular, the sample, in particular the type and number of the spins to be excited, as well as coupling constants between these spins, angle θ of the longitudinal axis Z′ of the transceiver coil relative to the static magnetic field B0 (Z-direction), excitation pulse sequence (including transmitted power on one or more channels, relaxation time of the spins, rotational speed of the measurement sample about the longitudinal axis Z′ of the transceiver coil.

According to the invention, the target function of optimization can therefore comprise the SNR itself or several variables influencing the SNR, which can be incorporated into the target function in a weighted manner. Alternatively, the target function can consist of multiple partial functions, for example one partial function per each selected variable influencing the SNR, which are iteratively optimized.

As a result of the optimization according to the invention with varying optimization parameters, shielding effects produced by the electrical conductor of the transceiver coil itself can be compensated. This results in an improvement in the quality (homogeneity) of the HF magnetic field B1 produced by the transceiver coil and of the signal strength of the NMR signal (amplitude of the HF magnetic field B1 produced by the transceiver coil), in particular for extended, for example band-shaped conductors. The optimization according to the invention preferably allows HF magnetic fields which have a component in the direction of the longitudinal axis Z′ of the transceiver coil. The optimization according to the invention therefore does not take place with the aim of avoiding Z′ components of the HF magnetic field B1. In contrast to Sun et. al. and U.S. Pat. No. 6,359,437, the invention therefore does not assume that the best solution is that in which the HF magnetic field B1 produced comes to lie as fully as possible in the XY-plane. In particular, the method according to the invention takes into account resistive losses which arise due to shielding currents on the coil conductors and reduction of the B1 field due to these shielding currents. These losses increase for extended conductors (conductors with non-vanishing conductor path width) with increasing tilt T, so that the best efficiency is generally achieved for HF magnetic fields B1 that are not completely in the XY-plane (plane perpendicular to the B0 field of a main field magnet).

The use of a strip conductor with a thickness of 3δ to 10δ, with δ=penetration depth at a given frequency and with a given coil material, is particularly advantageous.

The optimization preferably comprises:
a) defining the number N of windings, where N≥3,
b) determining in each case a starting value for the optimization parameters,
c) determining the target function with the determined starting values for the optimization parameters,
d) adjusting the optimization parameters, wherein for the at least two selected parameters a non-constant function is used as a function of a running parameter t running between 0 and winding number N of the transceiver coil arrangement, with t∈ [symbol] and 0≤t≤N N∈ [symbol]
e) determining the target function with the adjusted optimization parameters,
f) repeating steps d)-e) until the target function is within a predetermined target interval.

Preferably, the number N of windings is selected to be an integer or half-integer (N∈ [symbol] or 2N∈ [symbol] ). In principle, N can be E [symbol] .

In a preferred variant of the method according to the invention, one of the at least two variables of the target function influencing the SNR is the radial homogeneity of the HF magnetic field B1, which is produced by the transceiver coil during operation within the FOV, and the selected optimization parameters are the slope S and the tilt T of the windings.

In this variant, the target function therefore comprises, inter alia, the axial and radial homogeneity which are optimized via the tilt T and the slope S.

By using radial homogeneity as part of the target function, the SNR can be improved in particular by cross polarization (CP) and double cross polarization (DCP) experiments with a cross-coil arrangement having a transceiver coil according to the invention. While an infinitely long solenoid coil (except in the immediate vicinity of the windings) is characterized by a very high radial homogeneity, short solenoid coils have reduced radial homogeneity in the end region (at the axial ends), even if the axial homogeneity was corrected by reducing the slope of the windings in the end region. If such a short solenoid coil is used in MAS NMR measuring heads, the longitudinal axis Z′ of the transceiver coil is tilted by the magic angle about the Y-axis relative to the axis Z of the static magnetic field. Under these circumstances, the radial homogeneity of the HF magnetic field B1 decreases greatly in the edge region. This has a negative effect in particular on the achievable SNR of double cross polarization (CP) and double cross polarization (DCP) experiments, if, in addition to the first, a further transceiver coil is provided, and the two transceiver coils are matched to different measurement frequencies, in particular when the further transceiver coil is designed as a saddle coil and/or resonator, the B2 field of which points in the Y-direction (wherein the longitudinal axis Z′ of the first transceiver coil designed as a solenoid coil is located in the YZ-plane).

The optimization of the radial homogeneity takes place at a predetermined length L′ within the FOV parallel to the longitudinal axis Z′ of the transceiver coil (plateau region). The more similar the B1 intensity values along the plateau region (i.e., for different radii), the better the radial homogeneity.

Preferably, the tilt T of the windings is adapted over the course of the length of the electrical conductor such that the tilt T at the axial ends of the first transceiver coil is smaller than at the axial center.

For each conductor cross-section (i.e., in particular for each conductor path width W) and for each slope S there is a tilt T for which the B1 field amplitude is maximized. A variable tilt T with its maximum in the central region of the transceiver coil makes it possible to maximize the efficiency of the transceiver coil with simultaneously corrected radial homogeneity. In particular, the outermost 1-2 windings have a smaller tilt T compared to the tilt T of the windings that are arranged more towards the center.

Preferably, at least one half-winding in the center of the transceiver coil arrangement is tilted more strongly against the longitudinal axis Z′ of the transceiver coil than the longitudinal axis Z′ of the transceiver coil relative to a Z-axis defined by a static magnetic field B0 of the predetermined NMR experiment. As a result, in the case of extended conductors, it can be achieved that the B1 field runs in the XY-plane. The solution, which is found with this specification, is usually not the solution with maximum efficiency but a solution with maximum generated field strength per unitary current with reduced coil quality factor. This is advantageous in particular when very much loss occurs in other regions of the probe head and therefore the coil quality factor is not dominated by the conductor losses (but, for example, by dielectric loss . . . ).

The ratio D/W of gap width D to an adjacent winding and conductor path width W is preferably set as a function of the tilt of the windings. The gap width D of the conductor at position t is the distance of the electrical conductor between position t and position t+2π or t-2π.

If, in addition to the tilt T, the ratio D/W of gap width D and conductor path width W is selected as an optimization parameter, then the ratio D/W, i.e., either the conductor path width or the gap width, or both parameters along the length of the conductor, wherein the ratio D/W is selected as a function of the tilt T. That is, the larger the winding tilt T, the greater the ratio D/W of gap width D and conductor path width W is selected. In particular, D/W also varies over the length of a single winding, wherein D/W has at least two minima.

In an advantageous variant of the method according to the invention, one of the at least two variables influencing the signal-to-noise ratio SNR is the axial homogeneity of the HF magnetic field B1 produced by the transceiver coil. This takes place in particular by varying the slope of the windings. By optimizing the axial homogeneity (homogeneity along the longitudinal axis Z′ (on-axis)), it is possible, in particular, to improve the SNR of pulse sequences with several (90° and 180°) pulses or to increase the usable volume of the active region of the transceiver coil in which a desired signal quality, in particular a desired signal amplitude, is achieved.

For finite transceiver coils, the amplitude of the B1 magnetic field drops off at the axial ends. By reducing the slope at the axial ends, it can be achieved that the windings are situated closer together. In this way, the current density that is missing due to the finiteness of the transceiver coil can be compensated. Therefore, an improvement of the homogeneity along the longitudinal axis Z′ for short transceiver coils, which are operated at a distance from eigenfrequencies, results in particular when the slope at the axial ends of the transceiver coil is selected to be smaller than at the axial center.

During operation close to the eigenfrequency, when connecting the transceiver coil, it must be ensured that the electrical potentials are set such that the transceiver coil oscillates symmetrically, because otherwise the current distribution will change. Alternatively, a potential distribution can be set by means of a matching network such that the maximum is not in the center of the solenoid coil, but this leads to higher electrical fields and thus higher losses in lossy measurement samples.

A further variant of the method according to the invention provides that one of the at least two variables influencing the signal-to-noise ratio SNR is the B1 amplitude/rating, and the selected optimization parameters are the slope S and the conductor path width W. An optimization of the B1 amplitude/rating also comprises an iterative optimization of B1 amplitude/unitary current and quality factor. With the B1 amplitude/rating, the efficiency of the transceiver coil is improved.

When using, in particular, flat strip conductors as electrical conductors (with a conductor path thickness of 3δ to 10δ with δ=penetration depth), the sensitivity (B1 amplitude/rating) of the transceiver coil can be influenced by varying the ratio D/W of gap width D and conductor path width W. In particular, a deviation for the value P/W=1.5 . . . 1.667 known from the prior art for solenoid coils in the NMR is provided. For very thin metal platings and in particular also for coils having a significantly larger length than diameter, the highest efficiency of a solenoid coil is achieved according to the invention at a ratio of P/W<1.5, in particular <1.25. (i.e., at a pitch P of 1 mm with a conductor path width of 0.8 mm or more). The ratio of gap width D to conductor path width D/W is therefore preferably D/W<0.5, preferably D/W=0.25. Preferably, the gap width D between the windings is therefore smaller than or equal to half the conductor path width W, in particular smaller than or equal to a quarter of the conductor width.

The tilt T of the windings in the axial center of the transceiver coil is preferably selected such that the B1 amplitude of the HF magnetic field B1 produced by the transceiver coil is maximized per rating for a given ratio of gap width D to conductor path width W Here, the tilt T is thus an optimization parameter.

A special variant of the method according to the invention provides that the transceiver coil arrangement comprises a further transceiver coil for producing a further HF magnetic field B2 and that one of the at least two variables influencing the signal-to-noise ratio SNR is the ratio B1/B2 of the amplitude/rating of the first HF magnetic field B1 and of the further HF magnetic field B2.

To increase the efficiency of the coil, it is advantageous if the electrical conductor has a conductor thickness d and a rounding radius r, wherein the conductor thickness d and/or the rounding radius r of the electrical conductor is/are used as additional optimization parameters which varies/vary over the course of the length of the electrical conductor. This “blurs” a cumulation of current at the corner, increases the quality factor and thus the efficiency of the coil without having a significant influence on other parameters.

The invention also relates to a method for producing a transceiver coil. The transceiver coil is designed according to a previously described method, and the geometry of the coil is produced according to the design from a metallic tube, in particular by means of milling, laser or water jet cutting.

An advantage of this is the achievable small conductor path thickness d. Furthermore, such a transceiver coil can be manufactured without a carrier, in particular without a carrier between the conductor and the measurement sample, so that the efficiency of the transceiver coil is increased. To further improve the conductivity, methods for rounding the cut edges (e.g., trovalizing) of the conductor can be used, or the cut edges can be rounded, for example by milling.

Alternatively, the geometry of the coil according to the design can be realized by means of a coated carrier, wherein the coating is produced by structuring, for example etching, milling, laser ablation, etc. The production of a coating on a carrier enables the production of even thinner layers. The carrier helps to increase the mechanical robustness and can be used as a thermal conductor, for example in order to cool a cryogenic coil by means of a cold finger. The coating is preferably superconducting.

Further advantages of the invention will become apparent from the description and the drawings. Likewise, the features according to the invention that are mentioned above and set out in the following can each be used individually per se or together in any desired combinations. The embodiments shown and described are not to be understood as an exhaustive list but instead are of an exemplary nature for describing the invention.

### BRIEF DESCRIPTION OF THE DRAWINGS

FIG. 1 shows a transceiver coil according to the invention with a constant tilt in the center and reduced tilt of the outermost two windings, varying slope and periodically varying conductor path width with two maxima per winding for a single coil configuration.

FIG. 2 shows a transceiver coil with varying tilt, varying slope and periodically varying conductor path width with two maxima per winding for a cross-coil configuration.

FIG. 3a shows a plan view of a transceiver coil arrangement according to the invention in a cross-coil configuration with a first transceiver coil according to FIG. 2.

FIG. 3b shows a perspective view of the transceiver coil arrangement from FIG. 3a.

FIG. 4 shows a transceiver coil according to the invention with varying tilt, varying slope and periodically varying conductor path width with four maxima per winding for a cross-coil configuration.

FIG. 5a shows a plan view of a transceiver coil arrangement according to the invention in a cross-coil configuration with a zero-pitch transceiver coil with periodically varying slope and periodically varying conductor path width.

FIG. 5b shows a perspective view of the transceiver coil arrangement from FIG. 5a.

FIG. 6 shows a transceiver coil according to the invention for a single coil configuration, in which, in addition to the slope and the conductor path width, the tilt also varies, wherein the conductor path width varies periodically with a maximum in each revolution.

FIG. 7 shows a transceiver coil according to the invention with a slope varying from winding to winding, varying conductor path width and greatly varying tilt, wherein the conductor path width varies periodically.

FIG. 8 shows a transceiver coil according to the invention with a constant slope, varying conductor path width and varying tilt.

FIG. 9 shows an NMR probe head according to the invention.

FIG. 10a shows a detail of a solenoid-shaped coil section for illustrating the coil parameters in a coil with tilted windings.

FIG. 10b shows a detail of a solenoid-shaped coil portion for illustrating the coil parameters in a coil with non-inclined windings.

### DETAILED DESCRIPTION

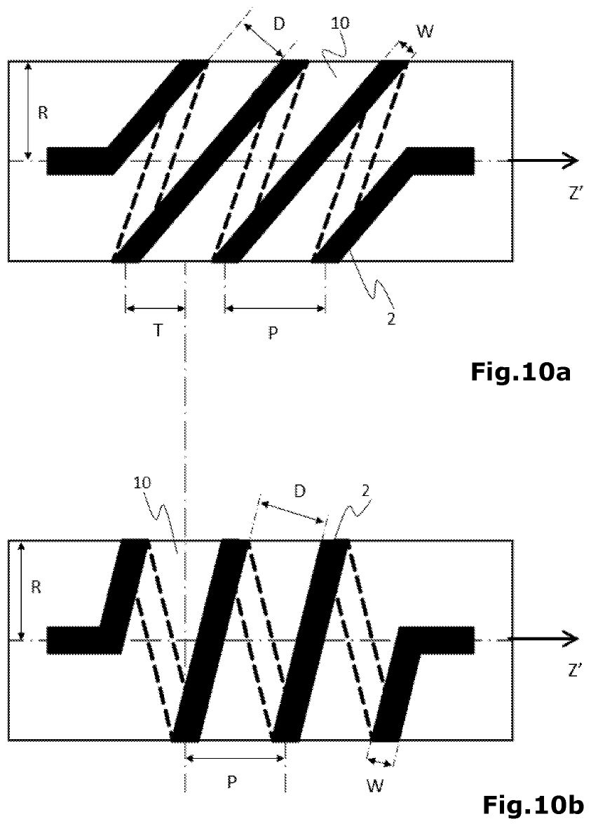

The transceiver coil according to the invention has coil parameters which vary along the course of the electrical conductor of the transceiver coil. FIG. 10a and FIG. 10b each show a section of a solenoid-shaped coil with a strip-shaped conductor 2 (conductor path), on the basis of which some of the coil parameters are first illustrated. The solenoid-shaped coils in FIG. 10a and FIG. 10b are arranged along a longitudinal axis Z′ (coil axis), wherein the longitudinal axis Z′ is perpendicular to an X′Y′-plane (not shown). The solenoid-shaped coils are parameterized by the conductor path width W of the conductor 2, a gap width D of a gap 10, a local slope S (not shown) and/or a pitch P of the windings, a tilt T of the windings, and a radius R of the windings. In the embodiment shown here, a total of three windings are shown.

The conductor width W indicates the width of the conductor 2. The conductor path width W is the width of the conductor path perpendicular to the conductor center. In the coils shown in FIG. 10a and FIG. 10b, the conductor path width W is constant along the longitudinal axis Z′ (i.e., W=const).

The gap width D indicates the width of the intermediate space 10 between the strip-shaped conductor of adjacent windings of the conductor path 2.

The pitch P of the windings indicates the propulsion in the Z′-direction of a complete winding and is determined via the central line of the conductor path 2. A constant pitch P does not exclude that the local slope S varies within one winding.

The inclination T of the windings indicates the inclination of the windings with respect to the longitudinal axis Z′ and corresponds to the amplitude of a sinusoidal modulation of the Z′ position of the conductor center plane over one winding. If the slope and tilt are constant over several windings, it can be easily determined from Max(Z(t)−Z(t+1))−S)/2, where t varies in the interval tn . . . tn+1.

The radius R of the windings indicates the radius on which the conductor 2 lies.

The solenoid coils shown in FIG. 10a and FIG. 10b each have a constant conductor path width W, a constant gap width D, a constant slope S and hence also a constant pitch P, with the coil shown in FIG. 10a being a tilted coil (T≠0), and the coil shown in FIG. 10b being a non-tilted coil (T=0).

In general, the central line of the conductor 2 is defined in Cartesian coordinates as

$$( \begin{matrix}R ( t ) * sin ( 2 π t ) \\ R ( t ) * cos ( 2 π t ) \\ P ( t ) * t + T ( t ) * cos ( 2 π t + φ )\end{matrix} ) ,$$

with t∈{0 . . . N}, where φ: Orientation of the inclination of the windings.

The envelope of the conductor 2 in Cartesian coordinates is defined as

$$( \begin{matrix}R ( t ) * sin ( 2 π t ) \\ R ( t ) * cos ( 2 π t ) \\ S ( t ) * t \pm W ( t ) / 2 + T ( t ) * cos ( 2 π t + φ )\end{matrix} ) , with t ∈ \{ 0 … N \} .$$

The conductor path width is in particular W(t)=W₀+ΣWᵢ (sin(2πt+k))²ⁱ, the tilt T is constant over each half-winding. Normally, the tilt direction is φ=0 (tilt about the Y′-axis) or π/2 (tilt about the X′-axis) and the radius R(t)=R.

In the following, various variants of the transceiver coil geometry according to the invention are described with which the performance of the NMR coil head according to the invention along the course of the electrical conductor 2 can be optimized by varying the coil parameters.

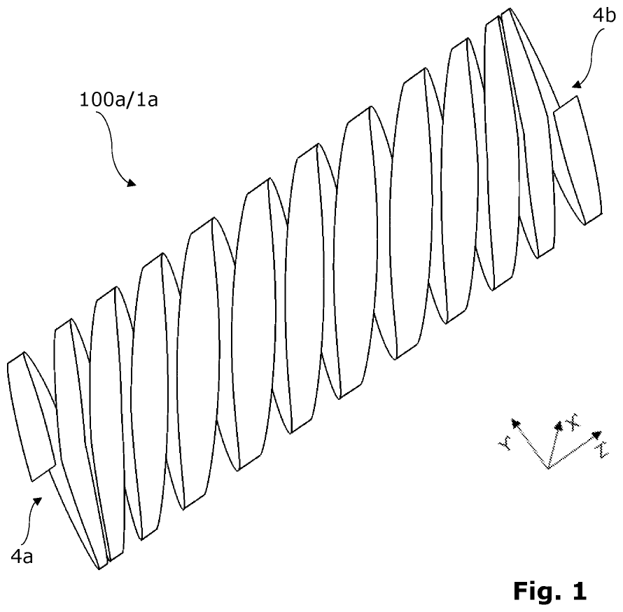

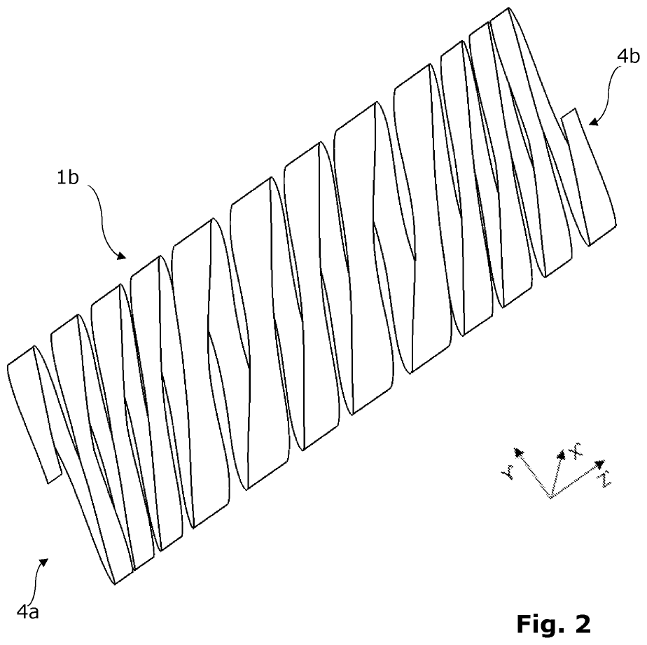

FIG. 1 and FIG. 2 show transceiver coils 1a, 1b according to the invention with a constant tilt T about the x′-direction (i.e., direction of tiltφ=π/2). The pitch P is constant in the central region of the transceiver coils 1a, 1b and decreases towards the two axial ends 4a, 4b of the transceiver coils 1a, 1b. The conductor path width W varies periodically and has two regions with maximum conductor path width per winding and two regions with minimum conductor path contact. Furthermore, W(k)=W(k+0.5)=Wmin and W(k+0.25)=W(k+0.75)=Wmax.

The parameters of the transceiver coils 1a, 1b varying according to the invention are the conductor path width W, as well as the pitch P and thus also the slope S. In these embodiments, the slope S is constant per winding. In general, however, it can also vary over the length of a winding.

The two transceiver coils 1a and 1b differ in terms of the arrangement of the minimum and maximum conductor path widths relative to the direction of tilt φ=π/2 or φ=0 the transceiver coils 1a, 1_{b}.

In principle, it is advantageous in the case of tilted windings (T≠0) if the minimum conductor path width on the sectional plane is orthogonal to the tilt axis. In the case of a tilt about the X′-axis, as shown in FIG. 1, the minima of the conductor path width lie on the sectional plane of the coil with the Y′Z′-plane. The tilt results in a field component being generated along a Y′-axis, i.e., 90° to Z′. This field component must “penetrate” the transceiver coil which is facilitated if a larger gap width D is present between the conductor sections of two windings. Shielding currents are formed on the conductors themselves, which increase resistive losses and weaken the field and thus lead to performance losses. The performance can be increased by positioning the minima of the conductor path width W or the maxima of the gap width D along the Y′Z′-plane and the maxima of the conductor path width W or the minima of the gap width D in the direction of the X′Z′-plane, since the ratio of gap width and conductor path width can be optimized at every spatial position.

Due to their good performance, the transceiver coil 1a shown in FIG. 1 is particularly suitable for transceiver coil arrangements 100a, 100b with a single coil configuration.

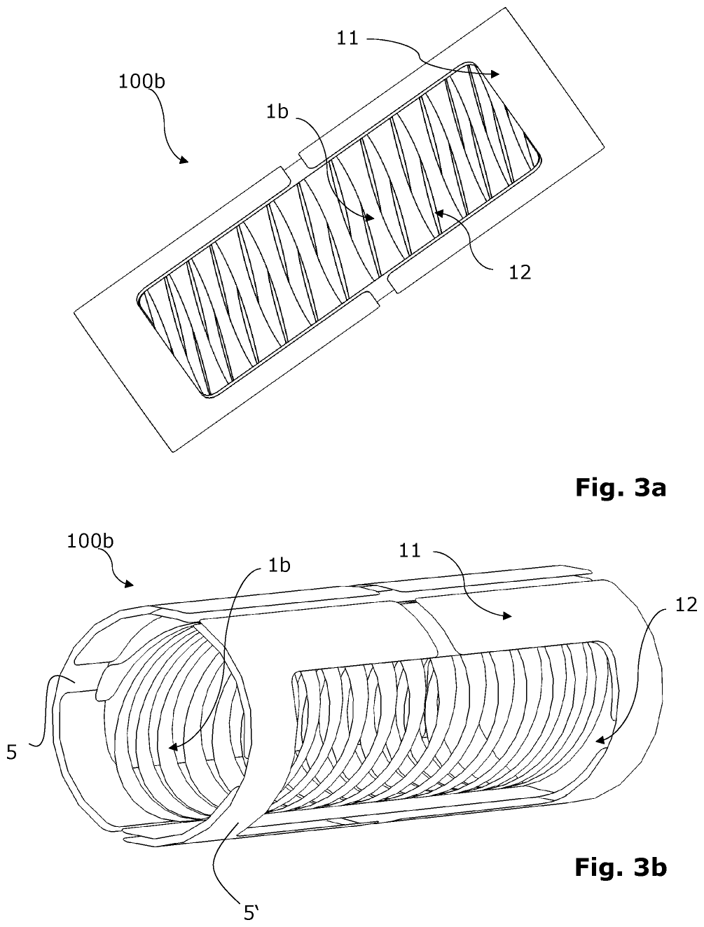

If a further transceiver coil 11 (see FIG. 3a and FIG. 3b) generating an HF magnetic field B2, which is oriented in the X′-direction (i.e., a saddle coil, a resonator, . . . ), surrounds or is surrounded by the transceiver coil 1b according to the invention, this field B2 must penetrate the first transceiver coil 1b. The conductor paths (windings) of the first transceiver coil 1b stand “in the way” and partially shield the field of the further transceiver coil 11. In this case, the performance of the further transceiver coil 11 can be optimized by reducing the conductor path width W of the first transceiver coil 1b in the direction of the X′-axis, as shown in FIG. 2. This optimization of the further transceiver coil 11 is “to the detriment of” the performance of the first transceiver coil 1b, but offers better permeability in the X′-direction. Therefore, the transceiver coil 1b shown in FIG. 2 is particularly suitable for transceiver coil arrangements 100b with a cross-coil configuration.

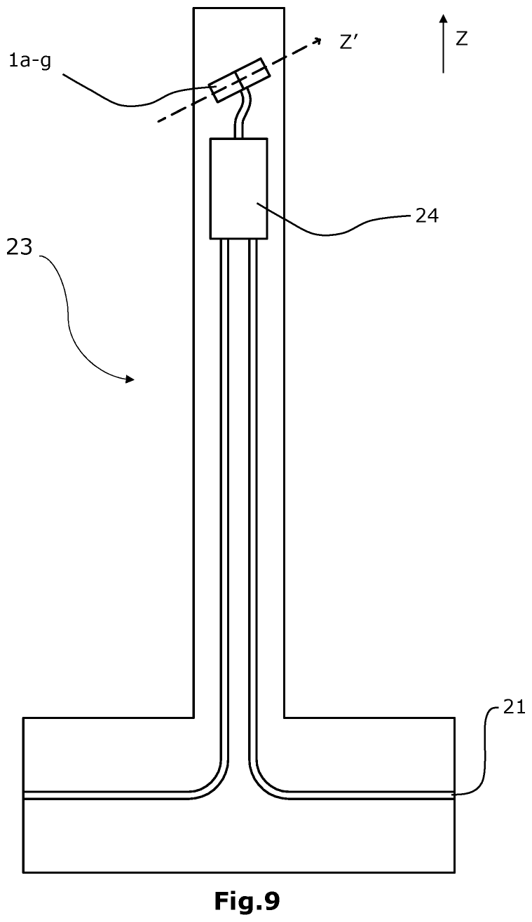

FIG. 3a and FIG. 3b show the transceiver coil arrangement 100b with such a transceiver coil 1b and a further transceiver coil 11 in a cross-coil configuration. The transceiver coil arrangement 100b comprises the first transceiver coil 1b shown in FIG. 2 for generating the first HF magnetic field B1 and the further transceiver coil 11 for generating the second HF magnetic field B2 for an NMR probe head 23 according to the invention (see FIG. 9). Here, the first transceiver coil 1b is arranged coaxially, radially inside the further transceiver coil 11, so that the second magnetic field B2 generated by the further transceiver coil 11 is substantially perpendicular to the first magnetic field B1 generated by the first transceiver coil 1b. The further transceiver coil 11 is formed here as an Alderman-Grant resonator consisting of two halves 5 and 5′, and radially surrounds the first transceiver coil 1b, wherein the further transceiver coil 11 comprises two opposite openings 12 (“windows”). The first transceiver coil 1b and the further transceiver coil 11 are oriented relative to one another in such a way that the regions of the first transceiver coil 1b, in which the conductor path width W of the electrical conductor 2 of the first transceiver coil 1 has minimum values, lie within the “windows” 12 of the further transceiver coil 11 so that the second magnetic field B2 generated by the further transceiver coil 11 runs through the regions with minimum conductor path width W of the first transceiver coil 1a. As a result, the first transceiver coil 1b has a high transparency for the second HF magnetic field B2. As an alternative to the embodiment shown in FIG. 3a and FIG. 3b, the further transceiver coil 11 can also be arranged within the first transceiver coil 1b (not shown). Likewise, the further transceiver coil can also be designed as a saddle coil, in particular as a multi-winding saddle coil instead of as a resonator (not shown).

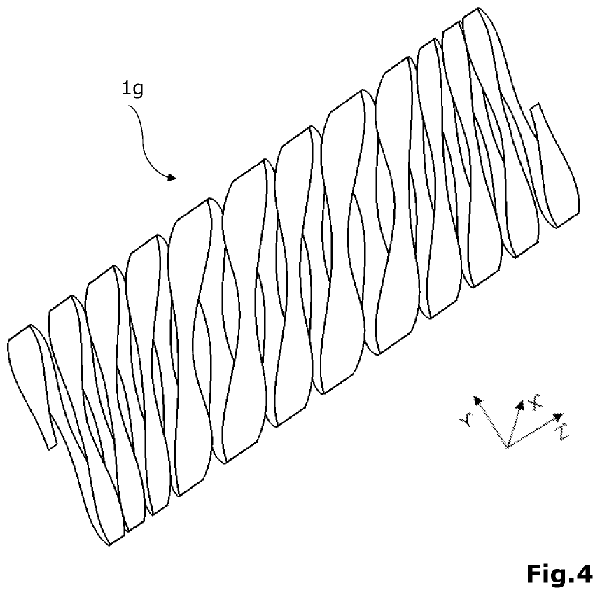

FIG. 4 shows a very specific embodiment of the transceiver coil 1g according to the invention. The conductor path width W changes periodically for the transceiver coil 1g and has four maxima and four minima per winding: two minima along the tilt axis (X′-direction) in order to—in analogy to the transceiver coil 1b from FIG. 2—create transparency for a second HF magnetic field B2 of a cross-coil configuration, and two minima perpendicular to the tilt axis (along the Y′-direction), in order to—in analogy to the transceiver coil 1a from FIG. 1—“get less in their own way.” These minima generally optimize the performance of the first transceiver coil 1g for transceiver coils with tilted windings, whereas the minima that increase transparency optimize the performance of the further transceiver coil (not shown in FIG. 4) at the expense of the first transceiver coil 1g.

The parameters of the transceiver coil 1g varying according to the invention are the conductor path width W, as well as the pitch P and thus also the slope S and the tilt T.

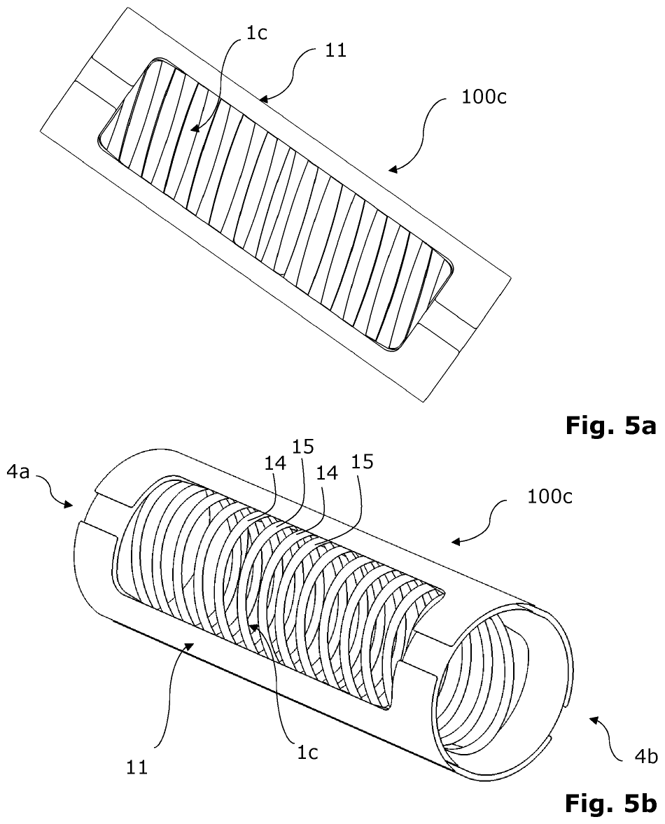

FIG. 5a and FIG. 5b show a further embodiment of a transceiver coil arrangement 100c in a cross-coil geometry with a first transceiver coil 1c. The windings of the transceiver coil 1c have a local slope S(t)=0 over a large part of their length. Such a winding forms a non-closed ring, i.e., S(t)=0 for t=t0 . . . t0+1-ε or t=t0+ . . . ε/2 . . . t0+1-ε/2, with ε>0, where E>0 prevents a short circuit; t=t0 is the beginning of the winding. Solenoid coils 1c designed in this way are known as “zero-pitch” coils, since a large part of the winding has a local pitch of 0. However, the pitch P of a complete winding has a value not equal to 0, which value is constant in this embodiment (|P|=const). Such a transceiver coil 1c can thus be designed as a combination of non-closed “rings” without (local) slope and sections of the electrical coil section with slope S(t)»0. The ratio W/D of conductor path width W to gap width D can be kept constant in a simple manner over the transceiver coil 1c if the conductor path width is designed to be constant. As a result, the quality of the transceiver coil 1c can be maximized, and/or the electrical fields can be minimized, in a particularly simple manner. However, the transceiver coil 1c in FIGS. 5a and 5b has a periodically varying conductor path width W, as a result of which the gap width D between the windings also varies periodically. The optimization of the performance of the one transceiver coil 1c and its influence on the performance of a cross-coil arrangement is particularly easy to calculate in this configuration. Furthermore, the transceiver coil 1c has a constant tilt T.

The parameters of the transceiver coil 1c varying according to the invention are the conductor path width W, the slope S or pitch P and the tilt T.

The first transceiver coil 1c shown in FIG. 5a and FIG. 5b is preferably designed in a crisscross geometry with forward windings 14 and return windings 15 which are preferably arranged alternately.

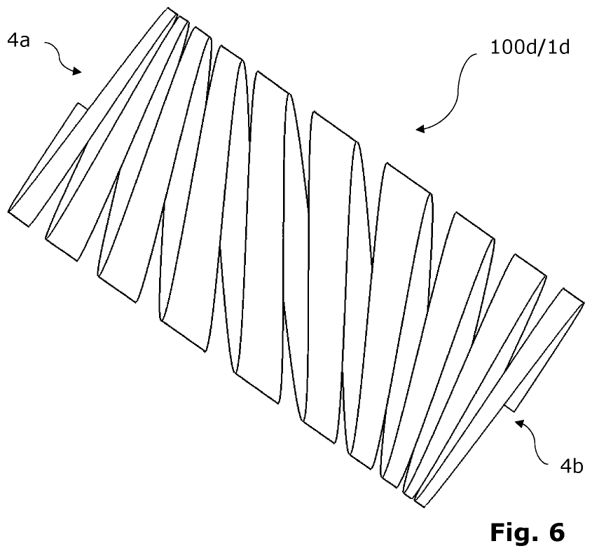

FIG. 6 shows a transceiver coil 1d according to the invention in which both the local slope S and the conductor path width W as well as the tilt T vary. The conductor path width W has exactly one maximum and one minimum in each winding, wherein the conductor path width W averaged over a winding decreases towards the axial ends 4a, 4b. The transceiver coil 1d from FIG. 6 can be particularly well matched to multiple cores and is therefore suitable in particular for a 1-coil transceiver coil arrangement 100d.

The parameters of the transceiver coil 1d varying according to the invention are the conductor path width W, the tilt T and the pitch P and thus also the slope S. The tilt T at the axial ends of the coil is T=0. As a result, such a coil can be mounted particularly easily in a defined installation space, for example between the bearings of an MAS stator, and makes particular good use of the available volume.

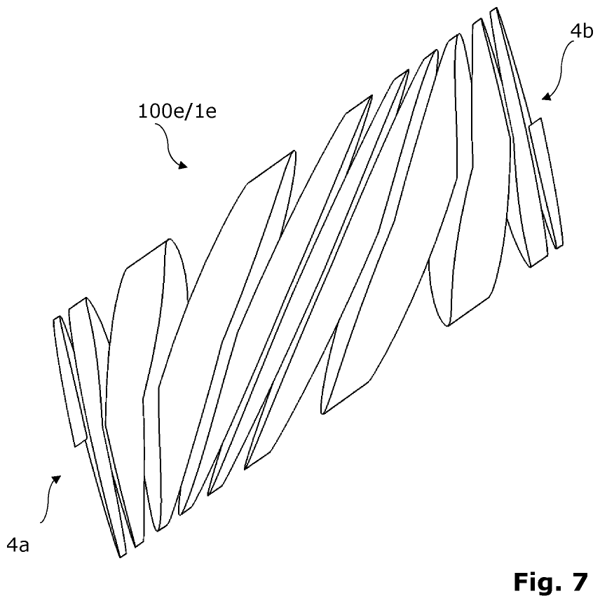

FIG. 7 shows a transceiver coil 1e according to the invention in which both the local slope S and the conductor path width W as well as the tilt T vary. In this embodiment, the slope S of the windings changes discretely, i.e., S(t)=constant within one winding. Although this discretization does not provide the optimum homogeneity, it allows for achieving a sufficiently good homogeneity level. Both the conductor path width W and the tilt T and pitch P decrease towards the axial ends 4a, 4b.

The parameters of the transceiver coil 1e varying according to the invention are the conductor path width W, the tilt and the pitch P and thus also the slope S.

The transceiver coil 1e is suitable in particular for a 1-coil transceiver coil arrangement 100e.

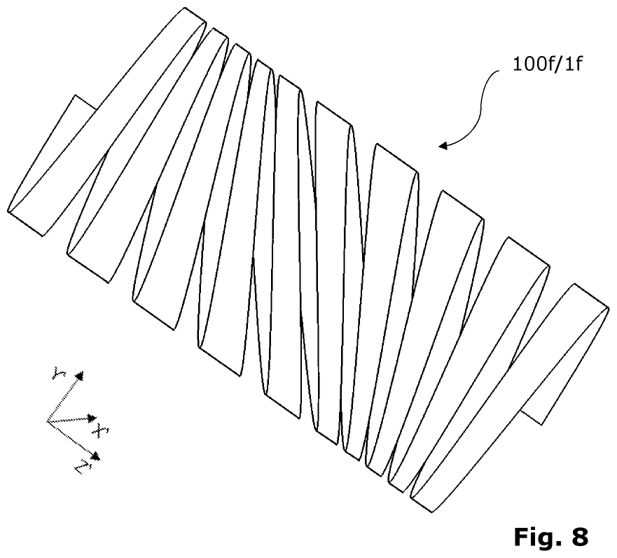

The transceiver coil if shown in FIG. 8 has a constant pitch P. However, the tilt T between the windings and the conductor path width W varies.

The ratio W/D of conductor path width W to gap width D between the windings is constant here. In combination with tilted windings (T not equal to 0), this results in the maximum conductor path widths W being arranged at the bottom (−Y′-direction) in windings of the left half of the transceiver coil 1f, while the maximum conductor path widths W are arranged at the top (+Y′-direction) in windings of the right half of the transceiver coil 1f. The transceiver coil 1f shown in FIG. 8 can be used particularly advantageously when the total length of the transceiver coil arrangement is limited, for example for a transceiver coil arrangement geometry, in which a transceiver coil has to be inserted between two bearings. The transceiver coil 1f can be used in particular for simple free induction decay (FID) experiments in which maximization of the axial and radial homogeneity is not necessary.

The parameters of the transceiver coil 1f varying according to the invention are the conductor path width W, the gap width D and the tilt T.

The transceiver coil 1f is suitable in particular for a 1-coil transceiver coil arrangement 100f.

FIG. 9 shows a schematic illustration of an NMR probe head 23 according to the invention. A static magnetic field for performing NMR measurements is aligned parallel to the Z-axis during operation in the example shown here. The NMR probe head 23 comprises a transceiver coil 1a-g or a transceiver coil arrangement 100a-f according to the invention, which is connected to the matching network 24 and further comprises a spectrometer connection 21. The NMR probe head 23 shown in FIG. 9 is a MAS (magic angle spinning) probe head in which the longitudinal axis Z′ of the transceiver coil 1 is tilted, preferably by the magic angle θ(θ=54.74°), with respect to the Z axis along which the elongated extension of the NMR probe head 23 extends.

### LIST OF REFERENCE SIGNS

1a-g Transceiver coils
2 Electrical conductor
4a, 4b Axial ends
5, 5′ Halves of the further transceiver coil
10 Intermediate space between windings
11 further transceiver coil
12 Openings/windows of the further transceiver coil
21 spectrometer connection
23 NMR probe head
24 matching network
100a-f Transceiver coil arrangements
Z′ Longitudinal axis of the transceiver coil
W Conductor path width
D Gap width
S Local slope
P Pitch
T Tilt
R Radius

1. A transceiver coil arrangement for an MAS NMR probe head having a first transceiver coil with a longitudinal axis Z′ for generating a first HF magnetic field B1, the first transceiver coil having at least one solenoid-shaped section which has an electrical conductor with a conductor path width W and N≥3 windings, wherein all of said windings run around the longitudinal axis Z′ of the transceiver coil, and wherein the electrical conductor has a slope S and each of said windings has a half-winding tilted at a tilt T relative to the longitudinal axis Z′, wherein T≠0 for at least a portion of the half-windings, the transceiver coil being configured such that at least two of the following parameters change over the course t of the length of the electrical conductor of the transceiver coil:
Tilt T=T(t),
Slope S=S(t),
Conductor path width W=W(t).

2. The transceiver coil arrangement according to claim 1, wherein the electrical conductor of the first transceiver coil is a band-shaped conductor.

3. The transceiver coil arrangement according to claim 1, wherein the slope S changes over the course t of the length of the electrical conductor, and wherein the conductor path width W changes within each winding.

4. The transceiver coil arrangement according to claim 1, wherein the slope S and the tilt T of the electrical conductor of the first transceiver coil change along the course of the electrical conductor.

5. The transceiver coil arrangement according to claim 4, wherein the tilt T at axial ends of the first transceiver coil is smaller than at an axial center.

6. The transceiver coil arrangement according to claim 1, wherein the transceiver coil arrangement comprises at least one further transceiver coil for generating a second HF magnetic field B2 radially outside the first transceiver coil, and
wherein the first transceiver coil and the further transceiver coil are arranged around the common longitudinal axis Z′ in such a way that HF magnetic fields B1, B2 generated by the first transceiver coil and the further transceiver coil are aligned perpendicular to each other.

7. The transceiver coil arrangement according to claim 1, wherein the electrical conductor of the first transceiver coil comprises a forward winding section and a return winding section,
wherein the forward winding section comprises forward windings and, starting from a connection region, leads in a predetermined winding sense to an axial end of the transceiver coil,
wherein the return winding section comprises return windings and, starting from the axial end of the first transceiver coil, leads to the connection region in the predetermined winding sense, wherein the windings of the return winding section have a slope S with sign opposite to those of the forward winding section, and
wherein forward and return windings of the electrical conductor, with the exception of crossover regions in which the forward and return windings cross over each other, are arranged on a common cylindrical jacket surface around the longitudinal axis Z′.

8. An MAS NMR probe head having a transceiver coil arrangement according to claim 1.

9. A method for producing a transceiver coil arrangement according to claim 1, the method comprising:
performing an optimization of a target function, wherein said target function is either the signal-to-noise ratio of a predetermined NMR experiment or a function that comprises at least two variables that influence the signal-to-noise ratio SNR, and wherein said optimization uses at least two optimization parameters that vary over the course of the length of the electrical conductor and that are selected from the following parameters:
Slope S,
Tilt T,
Conductor path width W, and
constructing the transceiver coil arrangement in accordance with the optimized target function.

10. The method according to claim 9, wherein said optimization comprises:
a) defining the number N of windings, where N≥3,
b) determining in each case a starting value for the optimization parameters,
c) determining the target function with the determined starting values for the optimization parameters,
d) adjusting the optimization parameters, wherein for the at least two selected parameters a non-constant function is used as a function of a running parameter t running between 0 and winding number N of the transceiver coil arrangement, with t∈ [symbol] and 0≤t≤N,
e) determining the target function with the adjusted optimization parameters, and
f) repeating steps (d)-(e) until the target function is within a predetermined target interval.

11. The method according to claim 9, wherein one of the at least two variables of the target function influencing the signal-to-noise ratio SNR is a radial homogeneity of the HF magnetic field B1, which is produced by the transceiver coil during operation within the field of view, and the selected optimization parameters are the slope S and the tilt T of the windings.

12. The method according to claim 11, wherein the tilt of the windings is adapted over the course of the length of the electrical conductor such that the tilt T at axial ends of the first transceiver coil is smaller than at an axial center of the first transceiver coil.

13. The method according to claim 9, wherein one of the at least two variables of the target function influencing the signal-to-noise ratio SNR is an axial homogeneity of the HF magnetic field B1 generated by the transceiver coil.

14. The method according to claim 9, wherein one of the at least two variables of the target function influencing the signal-to-noise ratio SNR is a B1 amplitude/rating, and the selected optimization parameters are the slope S and the conductor path width W.

15. The method according to claim 9, wherein the tilt T of the windings in a center of the transceiver coil is selected such that a B1 amplitude/rating is maximized for a given ratio S/W of slope S to conductor path width W.

16. The method according to claim 9, wherein the transceiver coil arrangement comprises a further transceiver coil for generating a further HF magnetic field B2, and one of the at least two variables of the target function influencing the signal-to-noise ratio is a ratio B1/B2 of the amplitude/rating of the first HF magnetic field B1 and the further HF magnetic field B2.

17. The method according to claim 9, wherein the electrical conductor has a conductor thickness d and a rounding radius r, wherein at least one of the conductor thickness d and the rounding radius r of the electrical conductor is used as an additional optimization parameter, which varies over the course of the length of the electrical conductor.

18. The method according to claim 9, wherein the transceiver coil is produced from a metallic tube using milling, laser or water jet cutting, and makes use of a coated carrier, wherein the coating is produced by etching, milling or laser ablation.
